(19) United States
(12) Patent Application Publication
(10) Pub. No.: US 2026/0056328 A1
(43) Pub. Date: Feb. 26, 2026

(54) ENHANCING RECEIVER OPERATION BY MODELING OSCILLATOR DRIFT

(71) Applicant: Higher Ground LLC, Palo Alto, CA (US)

(72) Inventor: Bruce Leonard MCKINLEY, South Riding, VA (US)

(21) Appl. No.: 18/810,889

(22) Filed: Aug. 21, 2024

(51) Int. Cl. G01S 19/23; H03J 7/04; H04B 1/16

(52) U.S. Cl. CPC G01S 19/235; H03J 7/04; H04B 1/163; H04B 1/1638

(57) ABSTRACT

According to one or more of the embodiments herein, systems and techniques are provided for demodulating a received signal which has rapidly varying frequency offset such as due to being transmitted or received with a system whose oscillator is rapidly varying or due to Doppler shift variation caused by change of relative motion between the transmitter and receiver, or due to frequency variations caused by a relaying device such as a communications satellite. The techniques herein establish a model for the carrier frequency and use it to compensate for the variations in frequency due to any source.

### TECHNICAL FIELD

The present disclosure relates generally to wireless communication systems, and, more particularly, to enhancing receiver operation by modeling oscillator drift.

### BACKGROUND

Oscillators are an important part of many electronic circuits. Oscillators may typically be used to generate waveforms, such as, but not limited to, sinusoidal waveforms. In communication circuits, for example, oscillators may be used to generate one or more waveforms (e.g., carrier signal, sinusoidal waveforms for up-conversion and/or down-conversion, etc.).

In communication systems, the waveform from an oscillator may be used to modulate a signal before it is transmitted and/or to demodulate a signal as it is received. To ensure proper demodulation of the received signal, it is critical to maintain the relationship between the frequency of the oscillator that modulates the signal and the frequency of the oscillator that demodulates the received signal. Failure to maintain this relationship forces the receiver to attempt to account for the errors in frequency and phase, and may prevent the receiver from being able to decode the information in the received signal.

### SUMMARY

According to one or more of the embodiments herein, systems and techniques are provided for modelling of the frequency of the oscillators. The modeled frequency is then used to compensate for the variation in the oscillator's frequency.

In one embodiment, a method of demodulating a received signal may comprise: determining, by a process, a plurality of carrier frequency estimates for respective segments of a signal received at a receiver; determining, by the process, one or more outlier estimates from among the plurality of carrier frequency estimates based on one or more criteria; and establishing, by the process, a model for the carrier frequency of the signal that minimizes an impact of the one or more outlier estimates. In one embodiment, the method further comprises: using the model for the carrier frequency to establish a compensated frequency that accounts for a frequency drift of an internal oscillator of either the receiver or a transmitter of the signal, or a relaying device such as a communications satellite. In still another embodiment, the method further comprises: using the compensated frequency to demodulate the signal.

Other embodiments of the present disclosure may be discussed in the detailed description below, and the summary above is not meant to be limiting to the scope of the invention herein.

### BRIEF DESCRIPTION OF THE DRAWINGS

The embodiments herein may be better understood by referring to the following description in conjunction with the accompanying drawings in which like reference numerals indicate identically or functionally similar elements, of which:

FIG. 1 illustrates an example of a Global Navigation Satellite Systems (GNSS) system;

FIG. 2 illustrates an example system that utilizes a communication system for determining location of a navigating device;

FIG. 3 illustrates an example of a packet;

FIG. 4 illustrates an example procedure for receiving and demodulating signals according to one or more embodiments herein;

FIG. 5A illustrates an example of a first stage of modeling a frequency of an oscillator according to one or more embodiments herein;

FIG. 5B illustrates an example of a second stage of modeling the frequency of the oscillator according to one or more embodiments herein;

FIGS. 6A-6B illustrate an example procedure for precisely determining and correcting carrier frequency and tracking phase variations throughout a reception process according to one or more embodiments herein;

FIG. 7 illustrates an example procedure for enhancing receiver operation by modeling oscillator drift according to one or more embodiments herein; and

FIG. 8 illustrates an example of a navigating device.

### DESCRIPTION OF EXAMPLE EMBODIMENTS

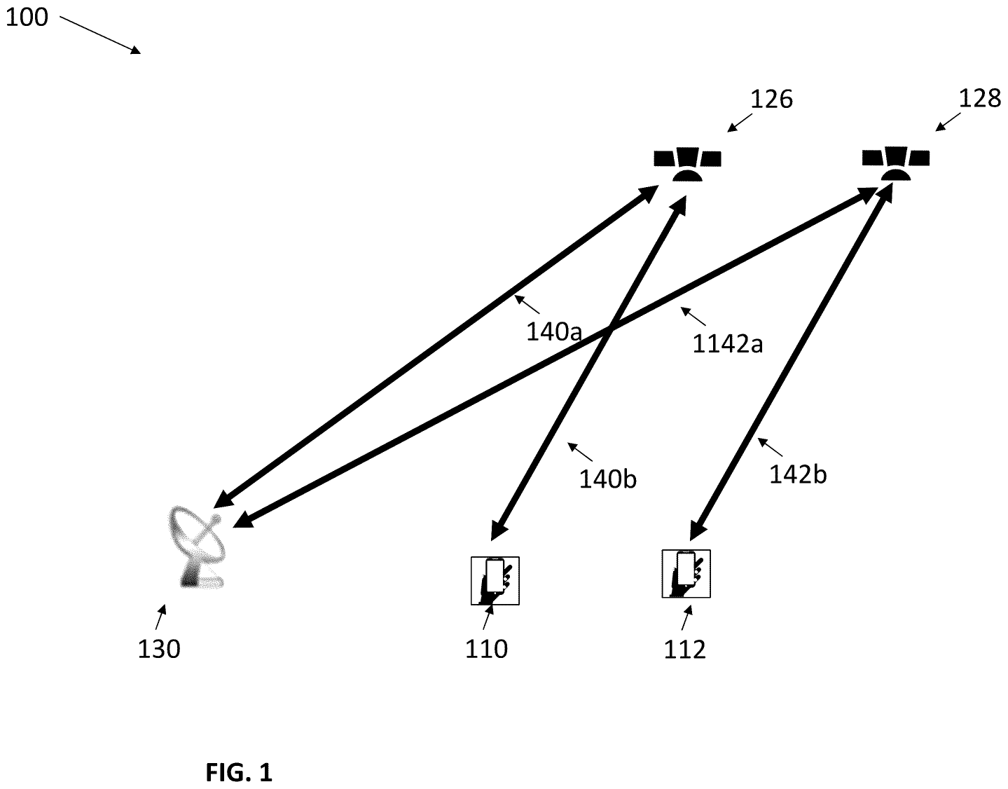

FIG. 1 is an example illustration of a simplified example communication system 100 that facilitates communication between two devices using a satellite or any other repeater. User device 110 uses repeaters (e.g., repeater 126 and/or repeater 128), such as communication satellites, to communicate with user devices 112. Communication device 110 sends a message to device 112 via link 140a and 140b to the ground station 130. The controller in the ground station identifies that device 112 can be reached via repeater 128 (e.g., a communication satellite) and sends the message to device 112 via communication links 142a and 142b. In another specific example, not shown for sake of simplicity, the communication controller in the ground station may utilize the same repeater/satellite and forward the message to device 112 via repeater 126 (e.g., another communication satellite).

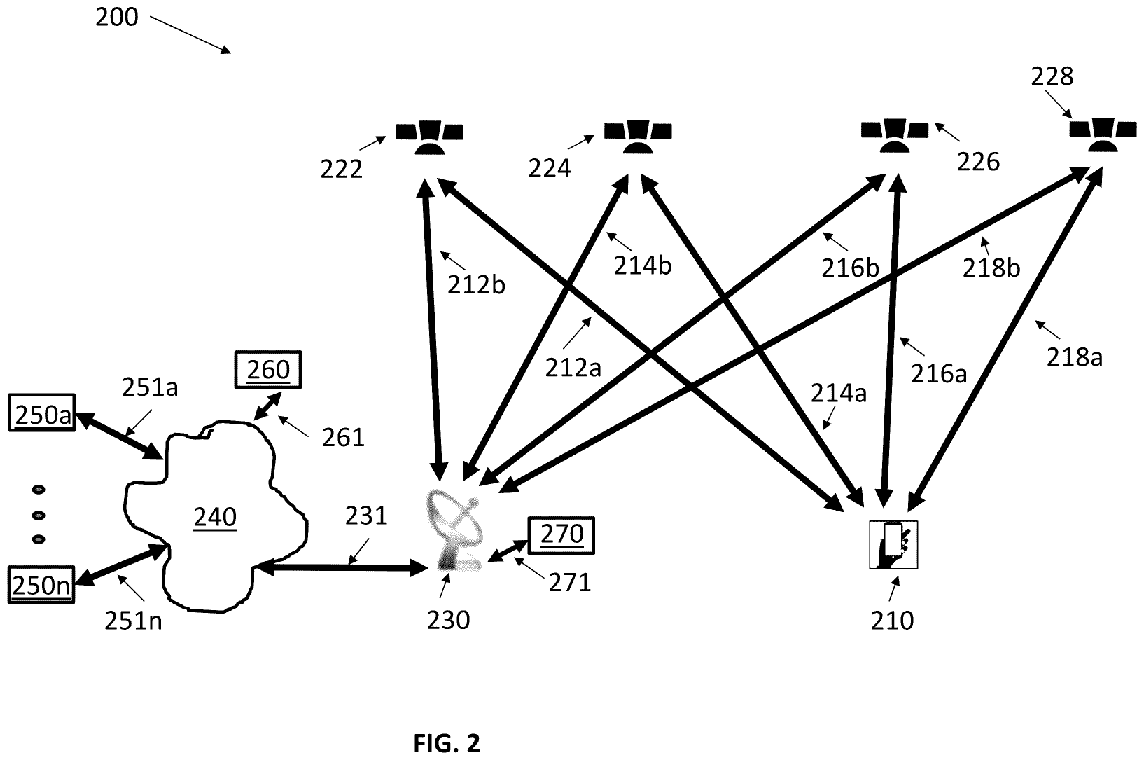

FIG. 2 illustrates an example communication system 200. User device 210 uses communication satellites such as satellites 222, 224, 226, 228 to communicate with user devices 250a through 250n. Communication satellites 222, 224, 226, and 226 and ground station 230 use communication links 212a, 212b, 214a, 214b, 216a, 216b, 218a, 218b, 231, 251a through 225n, and 261 and 271 to provide communication links for the communication infrastructure. Encryption server 260 performs encryption and decryption services on the transmitted and received messages. Receiver 270 performs frequency modeling and compensation to account for drift in the signal's carrier frequency and enable proper demodulation.

System 200 of FIG. 2 may also be used to provide location determination in accordance with the present disclosure. Communications system 200 includes a communications device, such as a handheld device 210, which sends and receives signals via communication links 212a, 214a, 216a, and 218a to and from communication satellites 222, 224, 226, and 228. In one specific scenario the communication satellites may be GEO satellites such as, but not limited to, a Tracking and Data Relay Satellite (TDRS). The signals which traverse communication links 112a, 114a, 116a, and 118a may be transponded or relayed from the satellites of the signals transmitted from the communications device. Alternatively, the signals from the satellites may be received and relayed via a ground station 230 using communication links 212b, 214b, 216b, and 218b between satellites 222, 224, 226, and 228 and ground station 230.

As noted above, the waveform from an oscillator may be used to modulate a signal before it is transmitted and/or to demodulate a signal as it is received. To ensure proper demodulation of the received signal, it is critical to maintain the relationship between the frequency of the oscillator that modulates the signal and the frequency of the oscillator that demodulates the received signal. As also noted above, failure to maintain this relationship forces the receiver to attempt to account for the errors in frequency and phase, and may prevent the receiver from being able to decode the information in the received signal.

Various methods were traditionally used to ensure that the frequency of the receiver's oscillator matches the frequency of the transmitter's oscillator. Some systems employ very accurate oscillators which are not as susceptible to frequency drift. However, due to size, power, and cost considerations, such oscillators may be used only in special applications where those factors are not a consideration. For many mobile devices, the size, power, and cost of such oscillators is prohibitive.

Other systems attributed the drift of the oscillator frequency to changes in the temperature of the oscillator and attempted to reduce the oscillator frequency drift by maintaining the temperature of the oscillator. Some systems maintain the temperature of the oscillator by placing it in an insulated environment. For example, in Fujii et al. (U.S. Pat. No. 6,163,688), an oscillator is encapsulated within a hermetically sealed case that is mounted beneath a circuit board. More elaborate systems placed the oscillators in temperature controlled environments. For example, Vonbun et al. (U.S. Pat. No. 3,071,736) teaches a method for stabilizing oscillator frequency by attaching the oscillator to a constant-temperature heat source. Other systems, called temperature compensated crystal oscillators, attempted to control the drift by measuring the temperature and feeding back a corrective voltage to the oscillator. For example, U.S. Pat. Nos. 5,986,515 and 7,816,993. For receivers that operate in a high signal to noise ratio (SNR) environment, the receiver may use a phase locked loop (PLL). The receiver's PLL circuit adjusts the frequency of the receiver's oscillator to ensure that it tracks (locks to) the frequency that was used to modulate the signal at the transmitter as well as any frequency offsets induced by relaying devices or relative motion. This adjustment may be done by directly adjusting the oscillator frequency, or in the digital signal domain using a frequency mixer. Further tracking of phase errors may also be accomplished by a PLL (often separate from the frequency tracking PLL). Frequency and phase tracking (and/or acquisition) may be particularly difficult in weak-signal environments, e.g., where the received signal-to-noise ratio (SNR) is very low. This may be done deliberately, e.g., using direct-sequence spread-spectrum (DSSS) or other spectral spreading techniques, for example, to avoid interfering with other signals transmitted in the same band, to allow multiple devices access in the same band, and/or to decrease detectability of the signaling by unintended receivers. It may also occur unintentionally, e.g., due to signal attenuation, intentional or unintentional electromagnetic interference from other sources, etc. One example is the transmission of DSSS signals over satellite links, where the DSSS signals have their energy purposely spread over a wide band (wider, at least, than a bandwidth that would normally be needed to transmit the signals, were they not spread), and where the satellite link may introduce significant attenuation, e.g., where the satellite used is in geosynchronous orbit.

In one such special case of DSSS, the data rate of the transmission is slowed down by using longer spread codes in order to intentionally reduce the transmit power to escape detection by an adversary. In another such special case the data rate of the transmission is slowed down by using longer spread codes and the power is kept at a nominal level in order to facilitate proper reception in the presence of degraded channel conditions that would otherwise disallow successful reception of the message. In this second case, the increase in energy will cause a heat rise, which in turn may cause excessive drift in the oscillator's frequency.

In many special cases with low SNR environments, the nominal phase noise inherent in an oscillator makes the acquisition and tracking of frequency and phase at the receiver difficult. In these cases, standard PLL methods fail, and other methods must be applied. For example, U.S. Pat. No. 9,692,587 describes a method of phase tracking in very low SNR environments.

In many other special cases, the frequency drift of the oscillator over short periods of time may vary enough to prevent the receiver from being able to properly demodulate the received signal. In many of these special cases, the variation in frequency of the oscillator is due, at least partially, to heat generated in the transmission process, e.g., induced by heat from the power amplifier.

Also, in still another case, the received carrier frequency may vary because of a Doppler effect caused by a relative motion between the transmitting and receiving devices.

Also, in still another case, the received carrier frequency may vary because of frequency offsets within a relaying device such as a communications satellite.

It may thus be desirable to provide a cost-effective solution to correct for the frequency and phase variations of an oscillator without relying on sufficiently high SNR or on stabilizing the temperature of the oscillator or otherwise controlling the oscillator in the transmitter and/or the receiver. It may further be desirable for the receiver to compensate for the drifts of the oscillator of a transmitting device by modeling the drift of the oscillator's frequency and compensating for it accordingly.

The techniques herein, therefore, model the frequency of the oscillators, which may then be used to compensate for the variation in the oscillator's frequency. In particular, the techniques herein can demodulate a received signal which has rapidly varying frequency offset, such as due to being transmitted or received with a system whose oscillator is rapidly varying or due to Doppler shift variation caused by change of relative motion between the transmitter and receiver or due to frequency offsets induced by a relaying device such as a communications satellite. That is, as described in greater detail below, the techniques herein establish a model for the carrier frequency and use it to compensate for the drifting frequency of the oscillator or drifts caused by Doppler effect.

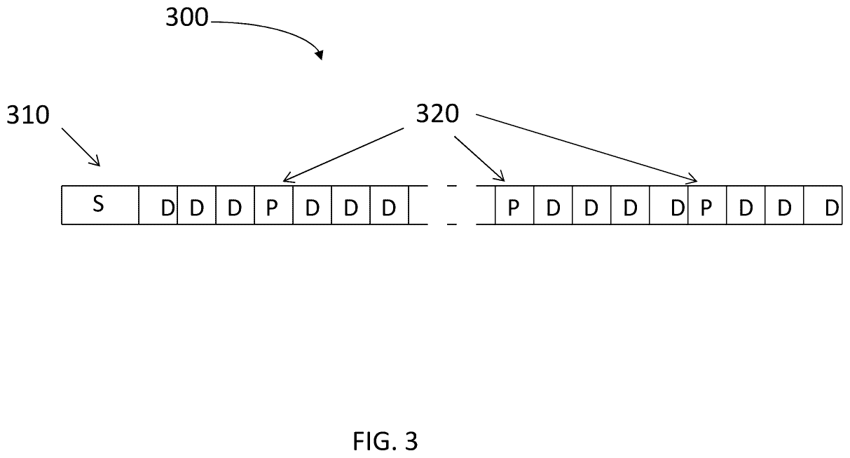

FIG. 3 illustrates a conceptual example of a packet, according to an aspect of the disclosure. The packet 300 may contain an embedded synchronization (“pilot”) pattern 320, where the synchronization symbols (or “pilot symbols”) of the sync pattern are denoted “P” in FIG. 3. Also, as noted above, a packet synchronization pattern may establish the starting point of a packet, and is represented by “S”, 310, in FIG. 3. The synchronization pattern S may be obtained from a pseudorandom sequence. The synchronization symbols S, 310, may also be obtained from a pseudorandom sequence, and they may be evenly distributed throughout the packet 300. The symbols marked “D” in the packet 300 may represent data or other symbols.

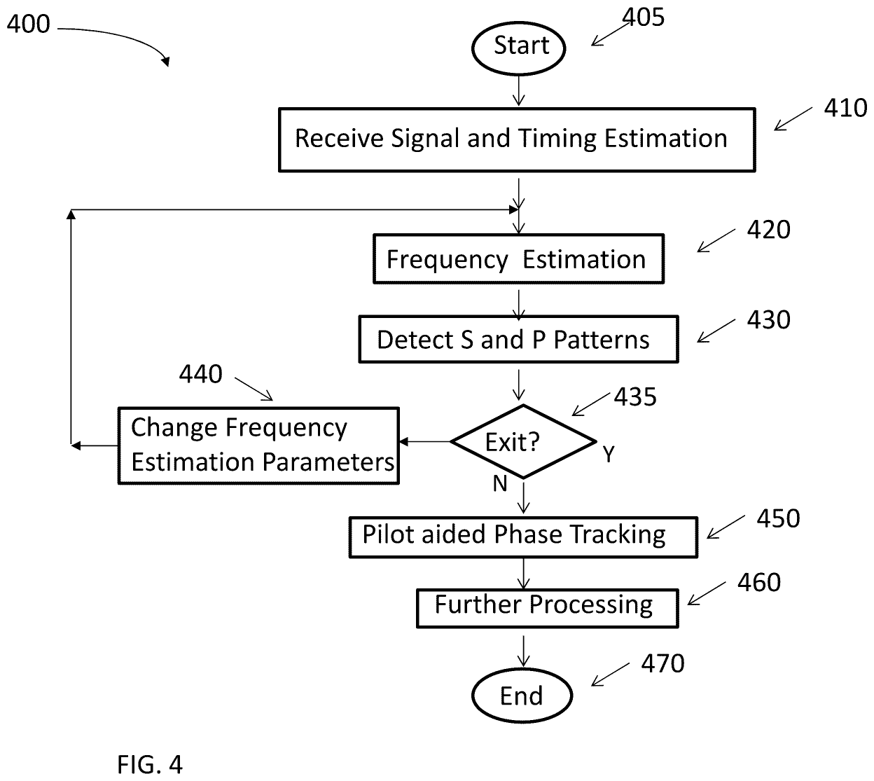

FIG. 4 illustrates a simplified conceptual flow diagram (process 400) for receiving and demodulating signals according to various aspects of this disclosure. A signal may be received, and candidate symbol sample instants may be obtained from the received signal; this may be done according to any method. Systems that operate according to the flowchart of FIG. 4 perform well when the oscillator and carrier tracking loop of the receiver are able to maintain substantially the same frequency as the oscillator of the transmitter.

However, initial frequency offset estimation may not be certain, e.g., because the transmitting oscillator frequency variation is too high or SNR is too low (and/or for other reasons), and this may lead to erroneous reception.

The process begins at operation 405 and proceeds to operation 410 where an input signal is received e.g., from the antenna of the device or from any other antenna associated with the device, and the symbol instants are determined using methods such as auto-correlation and/or non-coherent integration. In operation 420 a coarse estimate of the frequency offset of the received signal is estimated for example using methods such as “power-of-N” (for example as described in E.A. Lee and D.G. Messerschmitt, Digital Communications. Boston: Kluwer. Academic, 1993, ISBN: 0792393910). In operation 430 the signal is demodulated using the estimated frequency and the receiver attempts to detect the synchronization pattern, e.g., symbols “P” and “S” using methods such as for example cross-correlation. In operation 435 the results of the attempt to detect the synchronization symbols are evaluated, and a decision is made on whether to proceed with demodulation using the current frequency estimation parameters or to continue iteratively to perform new coarse frequency estimation.

If operation 435 determines that the current frequency estimation did not facilitate proper detection of the data including but not limited to the synchronization symbols, in operation 440 a new set of frequency estimation parameters is selected and the process loops back to operation 420 where the new set of parameters is utilized for providing a new frequency estimate and a detection of synchronization pattern P is attempted according to operations 420 and 430.

However, when operation 435 determines that demodulation should proceed, the process proceeds to operation 450 where the receiver performs fine carrier phase tracking using the pilots P. The resulting data symbols are used in operation 460 for further processing such as but not limited to decoding the data and determining the received information.

To increase the accuracy of the frequency estimation at low SNR, the estimation process utilizes a large number of samples of the received signal which are collected over a relatively long period of time. When the frequency of either transmitter or receiver oscillator is rapidly changing within the duration of a transmission, attempting to demodulate the information contained within the received signal with a single frequency estimate as in process 400 may not be reliable. Even after estimating the initial frequency offset and detecting the synchronization symbols S, the frequency variation over time due to drift of the oscillator, or for other reasons, may prevent the receiver from being able to reliably demodulate the incoming signal.

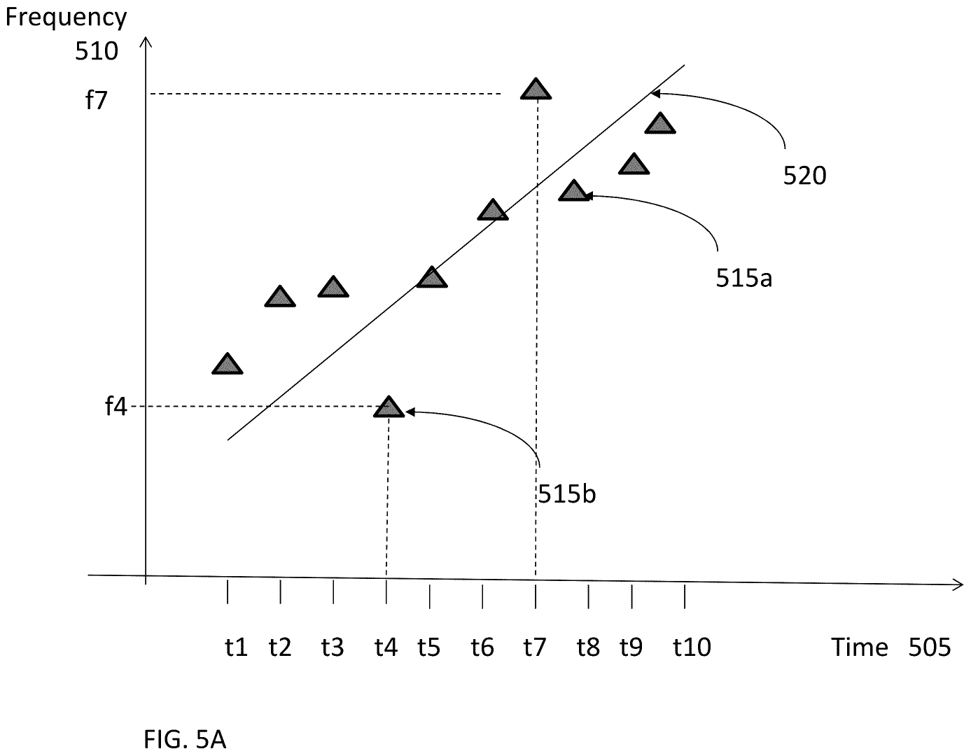

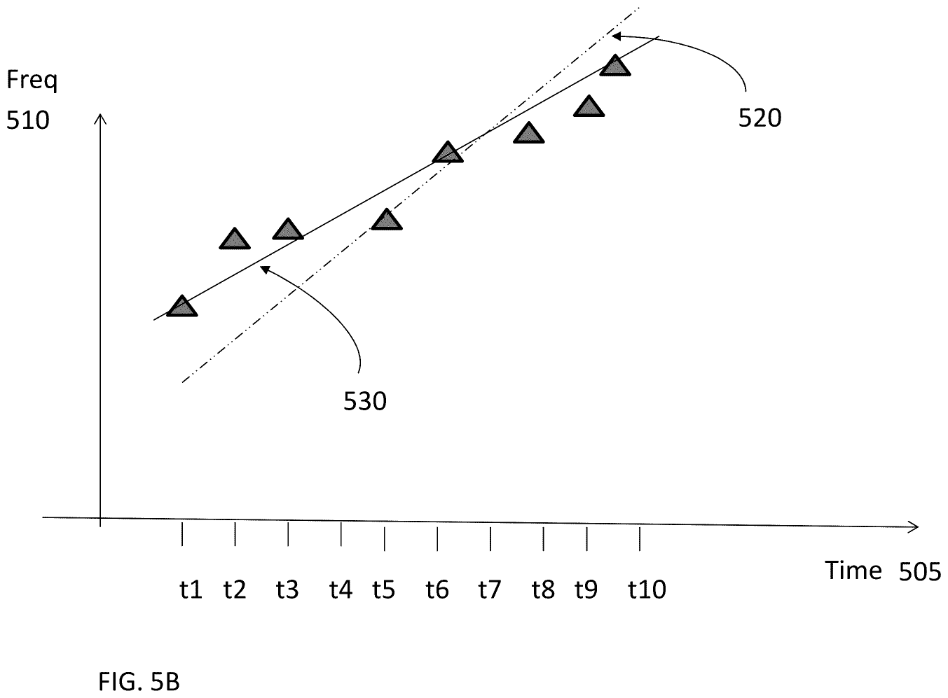

FIG. 5A provides an illustration of the first stage of an example system which models the frequency of the oscillator to mitigate the issues described above. Rather than assuming a slowly-varying carrier frequency and attempting to estimate an initial estimate based on a large number of samples, for example using samples from the duration of the transmission, the method assumes that the frequency of the carrier/oscillator is drifting rapidly. The method therefore attempts to estimate the carrier's frequency over much shorter time periods, or segments, using a much smaller number of received signal samples to perform the estimation. The smaller number of samples in a segment is determined by the absolute minimum length to produce at least mostly-reliable frequency estimates for a given signal SNR. This length is a function of the actual frequency drift encountered, the frequency estimation method and the received SNR. For example, rather than using “power-of-N” FFT of length 4096 the method uses FFT lengths of only 512 samples. The reduced number of samples in the estimate increases the frequency estimation error variance and causes the frequency estimate to be in error by some amount. At times a catastrophic estimation failure can occur due to noise or frequency drift when the peak of the “power-of-N” FFT result is in the incorrect FFT bin (i.e., the one not corresponding to the true frequency offset).

The result of such a frequency estimation process, including some catastrophic errors, is further illustrated in FIG. 5A. The X axis 505 illustrates the time corresponding to the segment of the received signal for which the frequency determination was made. The Y axis 510 illustrates the estimated frequency based on method such as “power-of-N” or any other frequency estimation method.

In accordance with one specific implementation, the frequency measurements (frequency estimates “515”, i.e., 515a-b) can be stored in memory as (time, frequency) pairs such as [(t1, f1), (t2, f2), (t3, f3), . . . (tn−1, fn−1) , (tn, fn)]. To reduce the impact of noise and catastrophic estimation errors associated with the time based frequency estimates, in accordance with one implementation, the method models the drifting frequency as a polynomial. FIG. 5A illustrates a simple example when the polynomial is a linear curve (model 520), however it should be understood that the invention contemplates polynomials of any other order or non-polynomial functions in time.

Using the initial model of the frequency drift (model 520) may not improve the receiver's ability to demodulate the input signal. A close examination of the model reveals that the model may incorporate several erroneous outlying frequency estimates. For example, the frequency samples (t4, f4) and (t7, f7) are identified as outliers 515b (as opposed to non-outliers 515a). To identify the outliers the method may start by fitting a polynomial to the frequency measurements such as a linear function (model 520). The method then determines the distance of the various frequency measurements from the curve and excludes the measurements which are farther away from the curve than a multiple of the RMS distance of the other measured frequencies. In accordance with another implementation the method determines the k-order differences between the frequency estimates such as for time tj the difference is fj−fj−k. For example, for k=1 the difference is fj−fj−1 or otherwise the difference between two consecutive frequency estimates. The method then identifies the outliers by comparing each one of the differences against the RMS frequency difference for all other measurements. The methods mentioned above for identifying outliers were brought only as an example; other methods for identifying outliers are contemplated by the present disclosure as well.

FIG. 5B illustrates a new linear model (model 530) of the carrier frequencies with the outlying carrier frequency measurements at times t4 and t7 being excluded. The present disclosure will refer to this model as a corrected carrier frequency model. Using the new model of the drifting oscillator frequency greatly improves the accuracy of the frequency track throughout the duration of the signal and in many cases allows the demodulation to continue using pilot symbols, and to ultimately successfully decode the data from the received signal.

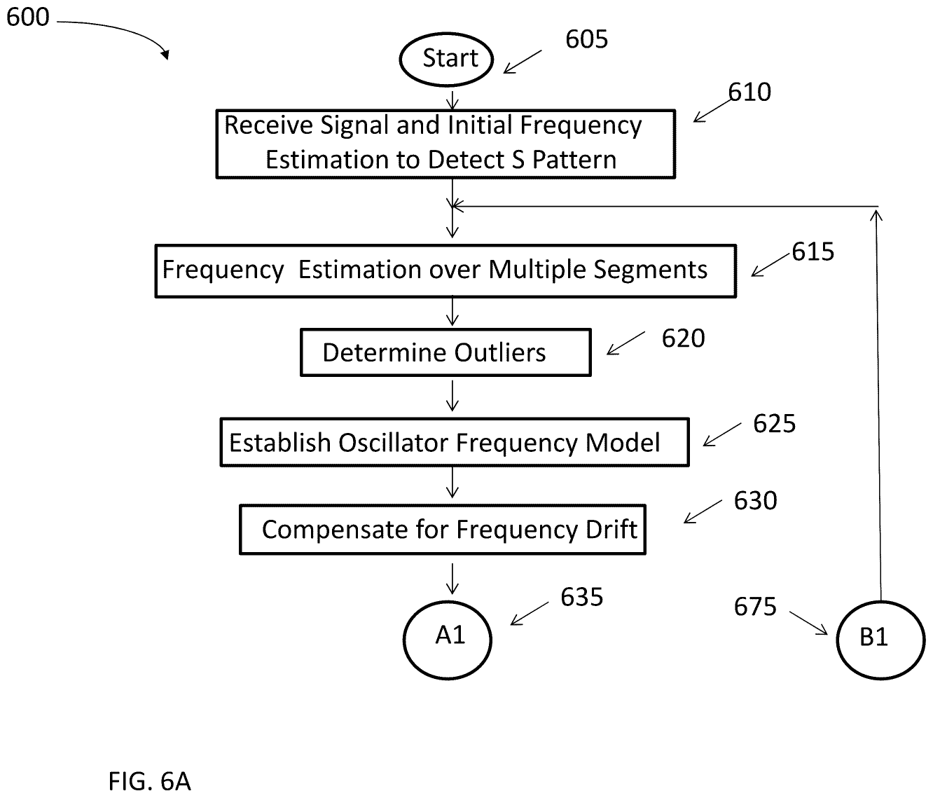

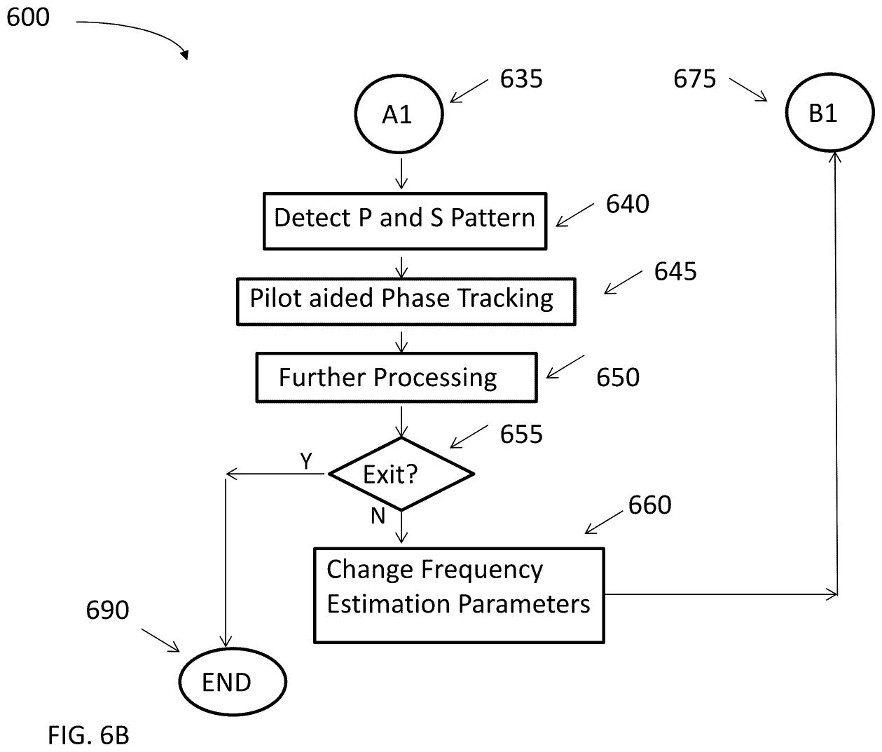

FIGS. 6A-6B illustrate a simplified conceptual iterative flow diagram (process 600) of an example implementation according to various aspects of this disclosure which can more precisely determine and correct carrier frequency and track phase variations throughout the reception process. A signal may be received, and candidate symbol sample instants may be obtained from the received signal; this may be done according to any method. Then initial frequency estimation and synchronization pattern detection is performed according to any method, for example the iterative method shown in FIG. 4.

According to the example flowchart of FIGS. 6A-6B, a process 600 starts at operation 605 and proceeds to operation 610 where input signal is received e.g., from the antenna of the device or from any other antenna associated with the device, and the synchronization symbol “S” instants are determined according to any method, e.g., such the methods described in association with FIG. 4. Operation 610 also incorporates initial frequency estimate and synchronization pattern detection operations according to any method, for example according to the method described above and shown in FIG. 4.

In operation 615 the frequency of the received signal carrier is estimated for example using methods such as “power-of-N. ” Other frequency estimation techniques are contemplated by this invention as well. However, unlike operation 420 which determined a single frequency based on a large number of received signal samples, operation 615 uses shorter segments as outlined above resulting in multiple frequency estimations for different portions of the incoming message. An example of the resulting frequency estimates is provided in FIGS. 5A-5B. In operation 620 outlier frequency measurements are determined, using one of the methods outlined above, and removed. The remaining measured frequencies are used in operation 625 to establish a model for the drifting frequency of the oscillator, e.g., by performing polynomial fitting. For sake of simplicity a polynomial curve fitting is discussed; however models other than a polynomial are contemplated as well. It should be noted that in one example implementation, the order of operations 620 and 625 may be changed or otherwise performed in an iterative manner. Specifically, the method may perform an initial model fitting; determine the distances of each frequency measurement from the model; identify the outliers as the measurements that are the furthest away from the model; remove the outliers; and perform another model fitting based on the remaining frequency measurements.

Operation 630 compensates for the drift in the oscillator by varying the frequency used to demodulate the received signal based on the established frequency model. It should be noted that unlike operation 420 wherein the frequency compensation utilizes a single estimated frequency before pilot symbol phase tracking, operation 630 uses the established model of carrier frequency over time, e.g., a drifting frequency model, to reduce total frequency offset throughout the reception.

The method proceeds via connector operation A1 635 to operation 640 where the pilot symbols are now able to be properly detected. Operation 645 tracks the carrier phase using pilot symbols P. This operation is similar to operation 450 of FIG. 4. Operation 650 utilizes the symbols which have been frequency- and phase-corrected to determine the received information using further processing such as, but not limited to, symbol detection, error-control decoding, etc.

In operation 655 the method examines one or more exit criteria such as determining whether the number of times the method loops around exceeds predetermined criteria, whether all of the frequency determination parameters, such as but not limited to FFT length, etc., have been examined, whether the error rate of the received symbols is below a predetermined threshold, etc. If the exit criteria are met, the method ends in operation 690. Otherwise, if the exit criteria are not met, a frequency estimation parameter, e.g., the length of the FFT, number of outliers to reject, etc., is modified in operation 660 and the method loops back to operation 615, via connector operator B1 675, where a new iteration of the time varying carrier frequency is estimated. In one example implementation operation 655 may determine and select the information that results from the best symbol detection (the one corresponding to the lowest bit error rate).

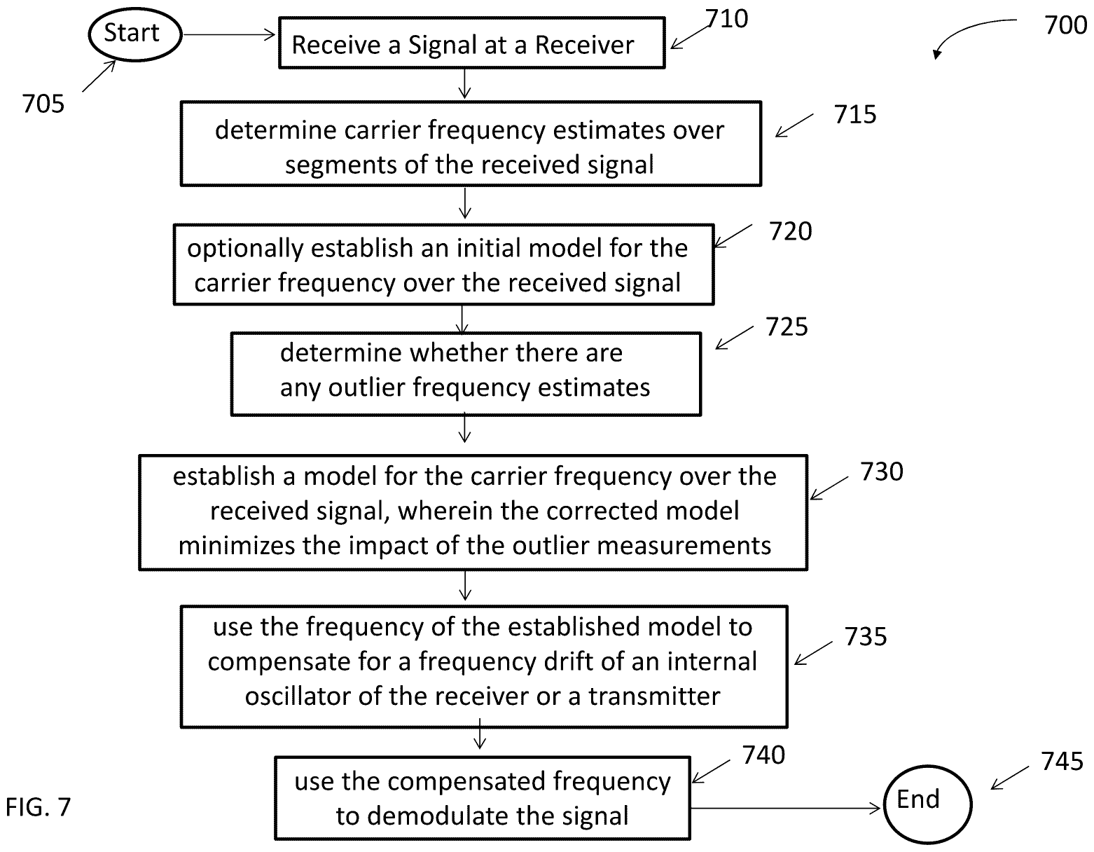

FIG. 7 illustrates an example simplified procedure (procedure 700) for enhancing receiver operation by modeling oscillator drift according to one or more embodiments herein. The procedure starts in step 705, and continues to step 710 where a device (e.g., a receiver) receives a signal. In step 715, the techniques herein determine a plurality of carrier frequency estimates for respective segments of the signal received at a receiver. In an illustrative embodiment, in step 720 the techniques herein may establish an initial/first model for a carrier frequency of the received signal based on the plurality of carrier frequency estimates (e.g., an “estimation model”).

In step 725, the techniques herein determine, one or more outlier estimates from among the plurality of carrier frequency estimates based on one or more criteria, such as, e.g., based on the first model for the carrier frequency. For instance, in one embodiment (e.g., based on step 720), the one or more outlier estimates may include any estimated frequencies of the plurality of carrier frequency estimates whose distance to the estimation model is greater than a first threshold. In other embodiments, the one or more outlier estimates may include any estimated frequencies of the plurality of carrier frequency estimates whose difference to another estimated frequency that is a configured number of segments apart is greater than or less than a particular threshold.

In step 730, the techniques herein establish a model (e.g., a “corrected model”) for the carrier frequency of the received signal that minimizes the impact of the one or more outlier estimates. In step 735, the techniques herein may use the model for the carrier frequency to establish a compensated frequency that accounts for a frequency drift of an internal oscillator of either the receiver or a transmitter of the signal. In step 740, the techniques herein may also use the compensated frequency to demodulate the signal. The procedure 700 ends in step 745, notably with the option to further iterate on the frequency modelling, accordingly.

It should be noted that while certain steps within the flowcharts may be optional and the steps shown in the Figures are merely examples for illustration, and certain other steps may be included or excluded as desired. Furthermore, while a particular order of the steps is shown, this ordering is merely illustrative, and any suitable arrangement of the steps may be utilized without departing from the scope of the embodiments herein. Moreover, the methods are described separately, certain steps from each procedure may be incorporated into one or more of the other methods and the various steps are not meant to be mutually exclusive.

Also, various operations described above may be performed by dedicated electronic hardware devices, or alternatively, may be implemented using other hardware, software, or firmware, or combinations thereof, including the possibility of using a processor that may execute software instructions, which may, e.g., be saved on a storage device, and which may cause the operations to be implemented.

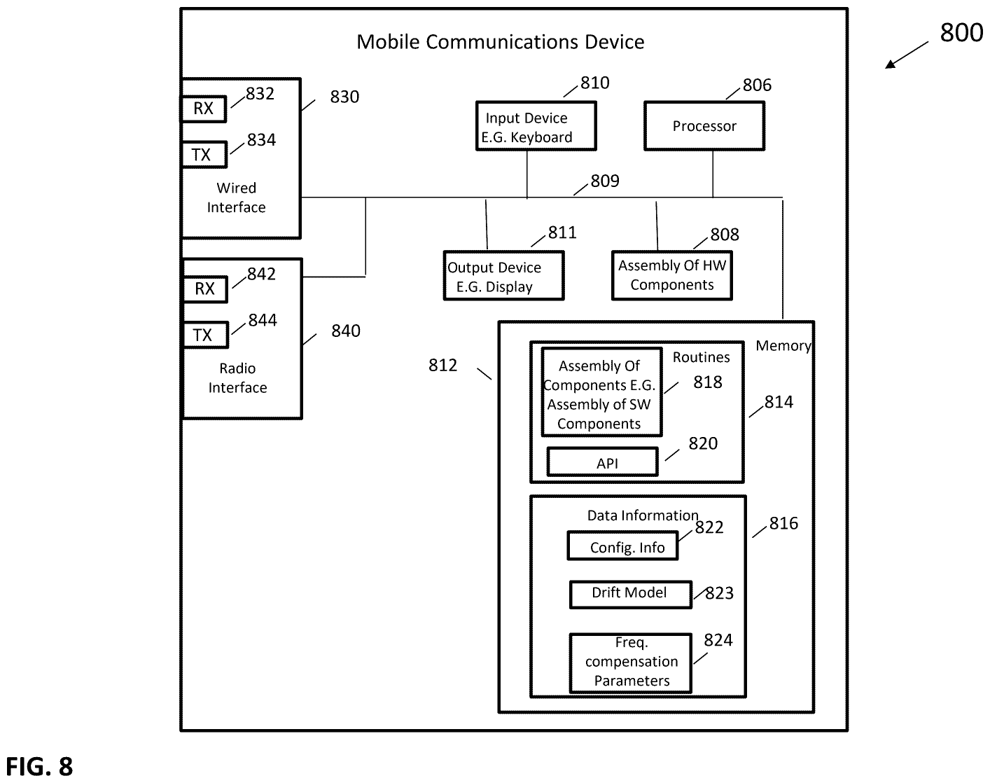

FIG. 8 is a drawing of communications device 800 in accordance with an example embodiment herein, e.g., as a particular device that may utilize the techniques herein (though any receiver may be configured in accordance with the techniques herein, and a communications device is merely one non-limiting example).

Communications device 800 includes wired interfaces 830, wireless interfaces e.g., radio interface 840, a processor 806, e.g., a CPU, a memory 812, and an assembly of modules 808, e.g., assembly of hardware module, e.g., assembly of circuits, coupled together via a bus 809 over which the various elements may interchange data and information. Wired interface 830 includes receiver 832 and transmitter 834. The wired interface and/or the wireless interface couples the navigating device 800 to a network and/or the Internet 240 of FIG. 2. Wireless radio interface 840 includes receiver 842 and transmitter 844. For sake of simplicity only one radio wireless interface is illustrated while the communicating device may include more than a single radio interface. The wireless interfaces 840 may support a Wi-Fi interface, e.g., 802.11 interfaces, satellite communication interface, Bluetooth interface, etc.

Memory 812 includes routines 814, and data/information 816. Routines 814 include assembly of modules 818, e.g., an assembly of software modules, and Application Programming Interface (API) 820. Data/information 816 includes configuration information 822, a model of the frequency drift 823 and frequency compensation parameters 824 to facilitate the compensation for the frequency drift of the oscillator.

Input device 810, e.g., keyboard, touch screen, etc., facilitates entering information, e.g., configuration information, into the communications device and output device 811, e.g., screen, LEDs, speakers, etc., facilitates conveying information by the communications device to an operator.

Advantageously, the techniques herein thus provide for enhancing receiver operation by modeling oscillator drift. According to the embodiments of the present disclosure, an illustrative method herein for enhancing receiver operation by modeling oscillator drift may comprise: determining, by a process, a plurality of carrier frequency estimates for respective segments of a signal received at a receiver; determining, by the process, one or more outlier estimates from among the plurality of carrier frequency estimates based on one or more criteria; and establishing, by the process, a model for the carrier frequency of the signal that minimizes an impact of the one or more outlier estimates.

In one embodiment, the method further comprises: using the model for the carrier frequency to establish a compensated frequency that accounts for a frequency drift of an internal oscillator of either the receiver or a transmitter of the signal or frequency drift induced by any other circumstance. In one embodiment, the method further comprises: using the compensated frequency to demodulate the signal. In one embodiment, the frequency drift is caused by one or more of a drifting frequency of the internal oscillator or a Doppler effect.

In one embodiment, the carrier frequency of the signal comprises a varying frequency.

In one embodiment, a duration of time of the respective segments is shorter than a frame duration.

In one embodiment, determining the one or more outlier estimates based on one or more criteria comprises one or more of: including, within the one or more outlier estimates, any estimated frequencies of the plurality of carrier frequency estimates whose distance to an estimation model initially established for the carrier frequency of the signal based on the plurality of carrier frequency estimates is greater than a first threshold; including, within the one or more outlier estimates, any estimated frequencies of the plurality of carrier frequency estimates whose difference to another estimated frequency that is a configured number of segments apart is greater than a second threshold; and including, within the one or more outlier estimates, any estimated frequencies of the plurality of carrier frequency estimates whose difference to another estimated frequency that is a configured number of segments apart is smaller than a third threshold. In one embodiment, the first threshold, the second threshold, and the third threshold are each selected from a group consisting of: a predetermined threshold; a dynamically adjusted threshold; and a relative threshold that is relative to statistics of the plurality of carrier frequency estimates.

In one embodiment, the method further comprises: removing the one or more outlier estimates from among the plurality of carrier frequency estimates; wherein establishing the model for the carrier frequency of the signal is based on remaining frequency estimates of the plurality of carrier frequency estimates after removing the one or more outlier estimates.

In one embodiment, establishing the model is based on a plurality of possible parameters, and the method further comprises: selecting one or more particular parameters for establishing the model to yield a least number of outlier estimates.

In one embodiment, establishing the model is based on a plurality of possible parameters, and the method further comprises: selecting one or more particular parameters for establishing the model to yield a lowest bit error rate.

In one embodiment, the model is a polynomial model.

In one embodiment, the signal is received from a satellite.

In one embodiment, the process is executed locally on the receiver.

Additionally, an illustrative apparatus herein may comprise: a processor configured to execute one or more processes; a communication interface; and a memory configured to store a process executable by the processor that when executed is configured to: determine a plurality of carrier frequency estimates for respective segments of a signal received at a receiver; determine one or more outlier estimates from among the plurality of carrier frequency estimates based on one or more criteria; and establish a model for the carrier frequency of the signal that minimizes an impact of the one or more outlier estimates. In one embodiment, the process is further configured to: use the model for the carrier frequency to establish a compensated frequency that accounts for a frequency drift of an internal oscillator of either the receiver or a transmitter of the signal. In still another embodiment, the process is further configured to: use the compensated frequency to demodulate the signal.

Moreover, an illustrative tangible, non-transitory, computer-readable medium herein may store program instructions that cause a computer of a particular device to execute a method comprising: determining a plurality of carrier frequency estimates for respective segments of a signal received at a receiver; determining one or more outlier estimates from among the plurality of carrier frequency estimates based on one or more criteria; and establishing a model for the carrier frequency of the signal that minimizes an impact of the one or more outlier estimates. In one embodiment, the method further comprises: using the model for the carrier frequency to establish a compensated frequency that accounts for a frequency drift of an internal oscillator of either the receiver or a transmitter of the signal. In still another embodiment, the method further comprises: using the compensated frequency to demodulate the signal.

Various aspects of the disclosure have been presented above. However, the invention is not intended to be limited to the specific aspects presented above, which have been presented for the purpose of illustration. Rather, the invention extends to functional equivalents as would be within the scope of the appended claims. Those skilled in the art, having the benefit of the teachings of this specification, may make numerous modifications without departing from the scope and spirit of the invention in its various aspects.

That is, while there have been shown and described illustrative embodiments, it is to be understood that various other adaptations and modifications may be made within the scope of the embodiments herein. For example, the embodiments may, in fact, be used in a variety of types of wireless communication networks and/or protocols, and need not be limited to the illustrative satellite network implementation. Furthermore, while the embodiments may have been demonstrated with respect to certain communication environments, physical environments, or device form factors, and in particular satellite communication environments, other configurations may be conceived by those skilled in the art that would remain within the contemplated subject matter of the description above, including other types of wireless communication mediums aside from satellite communications.

It will also be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules configured to operate in accordance with the techniques herein (e.g., according to the functionality of a similar process). Further, while the processes have been shown separately, those skilled in the art will appreciate that processes may be routines or modules within other processes.

Notably, in other embodiments, user intervention is not necessary at certain “user equipment”, and as such, various automated terminals, drones/UAVs, weaponry, etc., may employ the techniques herein. The use of the term “user” herein thus is not meant to be limiting to the scope of the types of devices implementing the techniques herein.

Furthermore, in the detailed description, numerous specific details are set forth in order to provide a thorough understanding of some embodiments. However, it will be understood by persons of ordinary skill in the art that some embodiments may be practiced without these specific details. In other instances, well-known methods, procedures, components, units and/or circuits have not been described in detail so as not to obscure the discussion.

In particular, the foregoing description has been directed to specific embodiments. It will be apparent, however, that other variations and modifications may be made to the described embodiments, with the attainment of some or all of their advantages. For instance, it is expressly contemplated that certain components and/or elements described herein can be implemented as software being stored on a tangible (non-transitory) computer-readable medium (e.g., disks/CDs/RAM/EEPROM/etc.) having program instructions executing on a computer, hardware, firmware, or a combination thereof. Accordingly, this description is to be taken only by way of example and not to otherwise limit the scope of the embodiments herein. Therefore, it is the object of the appended claims to cover all such variations and modifications as come within the true intent and scope of the embodiments herein.

What is claimed is:

1. A method, comprising:
determining, by a process, a plurality of carrier frequency estimates for respective segments of a signal received at a receiver;
determining, by the process, one or more outlier estimates from among the plurality of carrier frequency estimates based on one or more criteria; and
establishing, by the process, a model for a carrier frequency of the signal that minimizes an impact of the one or more outlier estimates.

2. The method as in claim 1, further comprising:
using the model for the carrier frequency to establish a compensated frequency that accounts for a frequency drift of an internal oscillator of either the receiver or a transmitter of the signal.

3. The method as in claim 2, further comprising:
using the compensated frequency to demodulate the signal.

4. The method as in claim 2, wherein the frequency drift is caused by one or more of a drifting frequency of the internal oscillator, a Doppler effect, or a relaying device such as a communications satellite.

5. The method as in claim 1, wherein the carrier frequency of the signal comprises a varying frequency.

6. The method as in claim 1, wherein a duration of time for of the respective segments is shorter than a frame duration.

7. The method as in claim 1, wherein determining the one or more outlier estimates based on one or more criteria comprises one or more of:
including, within the one or more outlier estimates, any estimated frequencies of the plurality of carrier frequency estimates whose distance to an estimation model initially established for the carrier frequency of the signal based on the plurality of carrier frequency estimates is greater than a first threshold;
including, within the one or more outlier estimates, any estimated frequencies of the plurality of carrier frequency estimates whose difference to another estimated frequency that is a configured number of segments apart is greater than a second threshold; and
including, within the one or more outlier estimates, any estimated frequencies of the plurality of carrier frequency estimates whose difference to another estimated frequency that is a configured number of segments apart is smaller than a third threshold.

8. The method as in claim 7, wherein the first threshold, the second threshold, and the third threshold are each selected from a group consisting of: a predetermined threshold; a dynamically adjusted threshold; and a relative threshold that is relative to statistics of the plurality of carrier frequency estimates.

9. The method as in claim 1, further comprising:
removing the one or more outlier estimates from among the plurality of carrier frequency estimates;
wherein establishing the model for the carrier frequency of the signal is based on remaining frequency estimates of the plurality of carrier frequency estimates after removing the one or more outlier estimates.

10. The method as in claim 1, wherein establishing the model is based on a plurality of possible parameters, the method further comprising:
selecting one or more particular parameters for establishing the model to yield a least number of outlier estimates.

11. The method as in claim 1, wherein establishing the model is based on a plurality of possible parameters, the method further comprising:
selecting one or more particular parameters for establishing the model to yield a lowest bit error rate.

12. The method as in claim 1, wherein the model is a polynomial model.

13. The method as in claim 1, wherein the signal is received from a satellite.

14. The method as in claim 1, wherein the process is executed locally on the receiver.

15. An apparatus, comprising:
a processor configured to execute one or more processes;
a communication interface; and
a memory configured to store a process executable by the processor that when executed is configured to:
determine a plurality of carrier frequency estimates for respective segments of a signal received at a receiver;
determine one or more outlier estimates from among the plurality of carrier frequency estimates based on one or more criteria; and
establish a model for a carrier frequency of the signal that minimizes an impact of the one or more outlier estimates.

16. The apparatus as in claim 15, wherein the process is further configured to:
use the model for the carrier frequency to establish a compensated frequency that accounts for a frequency drift of an internal oscillator of either the receiver or a transmitter of the signal, by a Doppler effect, or by a relaying device such as a communications satellite.

17. The apparatus as in claim 16, wherein the process is further configured to:
use the compensated frequency to demodulate the signal.

18. A tangible, non-transitory, computer-readable medium storing program instructions that cause a computer of a particular device to execute a method comprising:
determining a plurality of carrier frequency estimates for respective segments of a signal received at a receiver;
determining one or more outlier estimates from among the plurality of carrier frequency estimates based on one or more criteria; and
establishing a model for a carrier frequency of the signal that minimizes an impact of the one or more outlier estimates.

19. The tangible, non-transitory, computer-readable medium as in claim 18, wherein the method further comprises:
using the model for the carrier frequency to establish a compensated frequency that accounts for a frequency drift of an internal oscillator of either the receiver or a transmitter of the signal.

20. The tangible, non-transitory, computer-readable medium as in claim 19, wherein the method further comprises:
using the compensated frequency to demodulate the signal.
